(19) United States
(12) Patent Application Publication
(10) Pub. No.: US 2006/0110533 A1
(43) Pub. Date: May 25, 2006

(54) Methods and apparatus for forming a titanium nitride layer

(75) Inventors: Wan-Goo Hwang, Yongin-si (KR); Myeong-Jin Kim, Pyeongtaek-si (KR); Seung-Ki Chae, Seoul (KR); Hyun-Seok Lim, Suwon-si (KR); Kyoung-Ho Jang, Ansan-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/281,163

(22) Filed: Nov. 17, 2005

(30) Foreign Application Priority Data
Nov. 19, 2004 (KR) 10-2004-0094980

(51) Int. Cl. C23C 16/00; B05C 11/00

(52) U.S. Cl. 427/248.1; 118/715; 118/702

(57) ABSTRACT

A method of forming a titanium nitride layer by an atomic layer deposition process using a batch-type vertical reaction furnace is described wherein a first source gas including a titanium precursor is provided onto substrates loaded in a process chamber for a first time period; a first purge gas is introduced into the process chamber for a second time period shorter than the first time period; a second source gas including nitrogen is provided onto the substrates for a third time period substantially identical to the first time period; and, a second purge gas is introduced into the process chamber for a fourth time period substantially identical to the second time period. Titanium nitride layers having uniform thickness and good step coverage may thus be formed while realizing a greatly reduced manufacturing time.

### CROSS-REFERENCE TO RELATED APPLICATION

This application claims the benefit of priority under 35 USC § 119 to Korean Patent Application No. 2004-94980, filed on Nov. 19, 2004, the disclosure of which is incorporated herein by reference in its entirety.

### BACKGROUND OF THE INVENTION

1. Field of the Invention

Example embodiments of the present invention relate to methods used in forming a layer on a substrate and to an associated apparatus for forming the layer on the substrate. More particularly, example embodiments of the present invention relate to methods of forming a titanium nitride (TiN) layer on a semiconductor substrate and to an apparatus for forming the titanium nitride layer on the semiconductor substrate.

2. Description of the Related Art

Semiconductor devices are typically manufactured by executing various sequential processes on suitable semiconductor substrates such as on silicon wafers. For example, a deposition process is generally performed for forming a layer on a semiconductor substrate, and/or an oxidation process is typically carried out for forming an oxide layer on the semiconductor substrate or for oxidizing a layer previously formed on the semiconductor substrate. Additionally, a photolithography process is commonly carried out for forming a desired pattern on the semiconductor substrate by etching a layer formed on the semiconductor substrate. Further, a planarization process is typically performed for planarizing a layer formed on the semiconductor substrate.

Various layers of a semiconductor device may be formed through a chemical vapor deposition (CVD) process, a physical vapor deposition (PVD) process, an atomic layer deposition (ALD) process, etc. For example, a silicon oxide layer serving as a gate insulation layer or an insulating interlayer of a semiconductor device is usually formed by a CVD process. A silicon nitride layer serving as a mask pattern or a gate spacer is also typically formed by a CVD process. Additionally, various metal layers, such as metal wirings and electrodes, of the semiconductor device may also typically be formed by a CVD process, a PVD process, an ALD process, etc.

In a semiconductor device, a titanium nitride layer may be used as a metal barrier layer to prevent a metal from diffusing. Such a titanium nitride layer may be formed by a CVD process, a PVD process, an ALD process, etc. Such a titanium nitride layer may also serve as a metal wiring, a contact plug, or an upper electrode of a capacitor so as to prevent diffusion of metal ions toward a lower region of a semiconductor device, such as toward a gate of a transistor, a dielectric layer of a capacitor or the semiconductor substrate, where the metal could adversely affect the performance of the semiconductor device. Conventional methods of forming a titanium nitride layer are disclosed in U.S. Pat. No. 6,436,820 issued to Hu et al., U.S. Pat. No. 6,555,183 issued to Wang et al., and U.S. Patent Application Publication No. 2003/0186560, each of which is incorporated herein by reference.

When the titanium nitride layer is included in the upper electrode of the capacitor, the titanium nitride layer serves as a metal barrier layer formed on the dielectric layer. In such applications, a doped polysilicon layer that serves as part of the upper electrode, or alternatively a metal layer, is typically additionally formed on the titanium nitride layer.

In recent years, a unit cell of commercial semiconductor devices has gradually become greatly reduced in size as the semiconductor devices have increasingly become highly integrated. Hence, developments in semiconductor manufacturing technology have focused on obtaining proper structures in the reduced-sized unit cells. For example, the dielectric layer or the gate insulation layer is formed using a material having a relatively high dielectric constant, whereas the insulating interlayer is formed using a material having a relatively low dielectric constant to reduce a parasitic capacitance. Materials having a suitably high dielectric constant for such applications include Y₂O₃, HfO₂, ZrO₂, Nb₂O₅, BaTiO₃, SrTiO₃, etc.

It has been found that if the dielectric layer is formed using HfO₂, and the titanium nitride layer is formed on the dielectric layer by a CVD process, hafnium (IV) chloride (HfCl₄) may be generated by a reaction between HfO₂ and a TiCl₄ gas used as a source gas for forming the titanium nitride layer. Hafnium (IV) chloride may adversely affect the dielectric characteristics of the dielectric layer. Further, chlorine ions remaining in the titanium nitride layer may also damage the semiconductor device by increasing a specific resistance of the titanium nitride layer, thereby augmenting a contact resistance between the dielectric layer and the upper electrode including the titanium nitride layer. For example, the titanium nitride layer has been found to have a relatively high specific resistance of about 420 μΩcm when the titanium nitride layer is formed using TiCl₄ gas and NH₃ gas.

In a conventional method of forming a titanium nitride layer, the titanium nitride layer is formed at a temperature of about 680° C. in accordance with the reaction between TiCl₄ gas and NH₃ gas. The residual chlorine ions contained in the resulting titanium nitride layer may be reduced by increasing a reaction temperature of the TiCl₄ gas and the NH₃ gas. Using such a higher reaction temperature, however, is limited by the tradeoff that the step coverage of the titanium nitride layer may be improved as the reaction temperature is decreased.

In a batch-type vertical chemical vapor deposition (CVD) apparatus as disclosed in the above-mentioned U.S. Patent Application Publication No. 2003/0186560, a titanium nitride layer formed on a substrate may have irregular thickness depending on a distance between the substrate and a gas outlet or a direction in which source gases flow onto the substrate. Additionally, a process time for forming the titanium nitride layer may be greatly increased when the titanium nitride layer is formed using the described apparatus and an ALD process in which a TiCl₄ gas and an NH₃ gas are employed as the source gases.

These and other limitations of and problems with prior art techniques for forming a titanium nitride layer in a semiconductor device are overcome in whole or at least in part by the methods and apparatus of this invention.

### SUMMARY OF THE INVENTION

Example embodiments of the present invention provide a method of rapidly forming a titanium nitride layer as part of a semiconductor element such that the titanium nitride layer has substantially uniform thickness, good step coverage and low specific resistance, and is formed without causing damage to an underlying layer of the semiconductor element.

Example embodiments of the present invention further provide an apparatus for forming a titanium nitride layer having substantially uniform thickness, good step coverage and low specific resistance without causing damage to an underlying layer.

According to one aspect of the present invention, there is provided a method of forming a titanium nitride layer. In one method of manufacturing a titanium nitride layer according to the present invention, a titanium layer is formed on a substrate loaded in a process chamber by contacting a first source gas which includes an effective amount of a titanium precursor with the substrate for a first time period. The process chamber is then rapidly purged by introducing a first purge gas into the process chamber for a second time period which is substantially shorter than the first time period. The titanium layer is converted into a titanium nitride layer by contacting a second source gas which includes nitrogen with the titanium layer for a third time period which is substantially identical to the first time period. The process chamber is then rapidly purged by introducing a second purge gas into the process chamber for a fourth time period which is substantially identical to the second time period. Multiple substrates can be loaded into the process chamber and treated simultaneously as described above to form a titanium nitride layer on each one.

In an example embodiment of the present invention, multiple substrates may be vertically stacked and spaced at predetermined intervals. Each of the substrates may be loaded in parallel into the process chamber.

In another example embodiment of the present invention, the first source gas and the second source gas may be provided into the process chamber through a plurality of first nozzles and a plurality of second nozzles respectively, the first and the second nozzles being disposed in a parallel array adjacent to the respective substrates.

In another example embodiment of the present invention, the first purge gas and the second purge gas may be introduced into the process chamber through the first set of nozzles, and/or through the second set of nozzles, or, alternatively or additionally, through a third nozzle disposed between the first nozzles and the second nozzles.

In another example embodiment of the present invention, portions of the first and the second purge gases introduced through the first and/or the second nozzles may flow along surfaces of the substrates, and portions of the first and the second purge gases introduced through the third nozzle may be sprayed into an inner upper portion of the process chamber to effect a more complete and speedy purging of the chamber.

In still another example embodiment of the present invention, the process chamber may be maintained at a temperature of about 350 to about 550° C.

In another example embodiment of the present invention, the titanium precursor may be selected from the group consisting of TiCl₄, Ti(OtBu)₄, Ti(NMe₂)₄, Ti(NEt₂)₄ and Ti(NEtMe)₄.

In another example embodiment of the present invention, the second source gas may include an effective amount of NH₃.

In another example embodiment of the present invention, a ratio among the first time period, the second time period, the third time period and the fourth time period (measured in the same units) may be in a range respectively of about 1.0:0.4 to 0.8:1.0:0.4 to 0.8. Preferably, a ratio among the first time period, the second time period, the third time period and the fourth time period may be in a range of about 1.0:0.5:1.0:0.5.

In another example embodiment of the present invention, the first source gas may be carried using a first carrier gas, and the second source gas may be carried using a second carrier gas.

In another example embodiment of the present invention, a flow rate of the first purge gas may be about four times to about ten times greater than a flow rate of the first carrier gas.

In another example embodiment of the present invention, the flow rate of the first purge gas is substantially identical to the flow rate of the second purge gas, and the flow rate of the first carrier gas may be substantially identical to the flow rate of the second carrier gas.

In yet another example embodiment of the present invention, a flow rate of the first purge gas introduced through the set of first nozzles, a flow rate of the first purge gas introduced through the set of second nozzles, a flow rate of the second purge gas introduced through the set of first nozzles, and a flow rate of the second purge gas introduced through the set of second nozzles may be substantially identical to each other as well as to the flow rate of the first carrier gas or the flow rate of the second carrier gas.

According to another aspect of the present invention, there is provided an apparatus for forming a titanium nitride layer on a semiconductor element. The apparatus includes a process chamber, a boat or a support member disposed in the process chamber, a gas supply system, and a control unit. The boat is adapted to support a plurality of substrates to be treated. The gas supply system provides a first source gas, a first purge gas, a second source gas and a second purge gas as needed into the process chamber. The first source gas includes a titanium precursor of a type and in a concentration effective for forming titanium layers on each of the several substrates. The first purge gas primarily purges the process chamber. The second source gas includes nitrogen in a form and concentration effective for converting the titanium layers into titanium nitride layers. The second purge gas secondarily purges the process chamber. The control unit controls the gas supply system to provide the first source gas for a first time period, the first purge gas for a second time period substantially shorter than the first time period, the second source gas for a third time period substantially identical to the first time period, and the second purge gas for a fourth time period substantially identical to the second time period.

In an example embodiment of the present invention, the process chamber may have a vertically-oriented cylindrical shape including an open bottom face.

In another example embodiment of the present invention, the apparatus may further include a heating furnace, a manifold and a vertical driving unit. The heating furnace may be disposed to enclose the process chamber. The heating furnace may heat the process chamber to a desired process temperature. The manifold may be connected to a lower portion of the process chamber. The manifold may have a cylindrical shape including an open upper face and an open bottom face. The vertical driving unit may be operated to load/unload the boat carrying a plurality of substrates into/out of the process chamber through the manifold.

In another example embodiment of the present invention, the vertical driving unit may include a first motor for generating a rotation force, a lead screw revolved (turned) by the rotation force, and a horizontal arm coupled to the lead screw. The horizontal arm may be vertically moved by the lead screw.

In another example embodiment of the present invention, the apparatus may further include a lid member disposed on the horizontal arm to open and close the open bottom face of the manifold, and a turntable disposed on the lid member to support the boat.

In another example embodiment of the present invention, the vertical driving unit may further include a second motor mounted on the horizontal arm to generate a rotation force for rotating the boat, and a rotation axel coupled to the turntable through the horizontal arm and the lid member for transferring the rotation force to the boat.

In another example embodiment of the present invention, the apparatus may further include a heater for heating an inside region of the manifold.

In another example embodiment of the present invention, the substrates may be vertically loaded in the boat so as to be separated by predetermined intervals.

In another example embodiment of the present invention, the gas supply system may include a first gas supply unit, a second gas supply unit, a third gas supply unit, a first gas supply line, a second gas supply line, a third gas supply line, and connection lines. The first gas supply unit may provide the first source gas, and the second gas supply unit may provide the second source gas, as needed. The third gas supply unit may provide the first purge gas and the second purge gas, as needed. The first gas supply line may transfer the first source gas into the process chamber, and the second gas supply line may transfer the second source gas into the process chamber, as needed. The third gas supply line may transfer the first purge gas and the second purge gas into the process chamber, as needed. The connection lines connect the third gas supply unit to the first gas supply line and the second gas supply line, as needed.

In another example embodiment of the present invention, the gas supply system may further include a first nozzle pipe, a second nozzle pipe and a third nozzle pipe. The first nozzle pipe may be connected to the first gas supply line and may be vertically extended adjacent to the substrates in the process chamber. The first nozzle pipe may include a plurality of first nozzles for providing the first source gas, the first purge gas and the second purge gas onto the substrates. The second nozzle pipe may be connected to the second gas supply line and may be extended in parallel relative to the first nozzle pipe in the process chamber. The second nozzle pipe may include a plurality of second nozzles for providing the second source gas, the first purge gas and the second purge gas onto the substrate. The third nozzle pipe may be disposed between the first nozzle pipe and the second nozzle pipe, and may be extended in parallel relative to the first and second nozzle pipes. The third nozzle pipe may include a third nozzle for providing the first purge gas and the second purge gas into the process chamber.

In another example embodiment of the present invention, the third nozzle may be formed through an upper end portion of the third nozzle pipe. The third nozzle may vertically spray the first purge gas and the second purge gas toward a ceiling region of the process chamber to enhance the effectiveness of a purge step.

In another example embodiment of the present invention, the third nozzle may have an inner diameter larger than the inner diameter of either the first or the second nozzles.

In still another example embodiment of the present invention, the first gas supply unit may include a first reservoir, a second reservoir, a vaporizer, a valve installed in a first connection line, and a liquid mass flow controller installed in a second connection line. The first reservoir provides a carrier gas, and the second reservoir stores the titanium precursor, typically in a liquid phase. The vaporizer is connected to the first and the second reservoirs. The vaporizer evaporates the titanium precursor in the liquid phase. The first connection line connects the first reservoir to the vaporizer. The valve controls a flow rate of the carrier gas. The second connection line connects the second reservoir to the vaporizer. The liquid mass flow controller controls a flow rate of the titanium precursor in the liquid phase.

According to the present invention, the titanium nitride layers may have a thickness of about 0.2 to about 0.3 Å after performing one unit cycle of an ALD process as described above. Titanium nitride layers formed in accordance with this invention have been found to demonstrate good step coverage. Since the substrates are, preferably, constantly revolved during the unit deposition cycle, each of the titanium nitride layers will have substantially uniform thickness. When the titanium nitride layer is formed using a TiCl₄ gas and an NH₃ gas, chlorine ions may be removed by a reaction between the chlorine ions and the NH₃ gas so that the titanium nitride layer will have a low specific resistance, and an underlying dielectric layer (which typically includes hafnium oxide) will have enhanced dielectric characteristics. Furthermore, since a process chamber for forming the titanium nitride layers is rapidly purged after each step in a formation of the titanium nitride layers, the processing time for forming the titanium nitride layers is greatly reduced compared with prior art techniques.

These and other advantages and invention embodiments will be better understood by reference to the accompanying drawings.

### BRIEF DESCRIPTION OF THE DRAWINGS

Example embodiments of the present invention will become readily apparent by reference to the following detailed description when considered in conjunction with the accompanying drawings wherein:

FIG. 1 is a schematic cross-sectional view illustrating an apparatus for forming a titanium nitride layer in accordance with an exemplary embodiment of the present invention;

FIG. 2 is a block diagram illustrating a gas supply system for an apparatus for forming the titanium nitride layer as seen in FIG. 1;

FIG. 3 is a perspective view schematically illustrating a first nozzle pipe, a second nozzle pipe and a third nozzle pipe of the gas supply system shown in FIG. 2;

FIG. 4 is a block diagram illustrating a gas supply system in accordance with another exemplary embodiment of the present invention;

FIG. 5 is a timing diagram illustrating a sequence of supply times of source gases and purge gases using the gas supply system shown in FIG. 2; and

FIG. 6 is a flow chart illustrating a method of forming a titanium nitride layer in accordance with an exemplary embodiment of the present invention.

### DETAILED DESCRIPTION OF THE EXAMPLE EMBODIMENTS

The present invention is described more fully hereinafter with reference to the accompanying drawings, in which illustrative embodiments of the present invention are shown. The present invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions are sometimes exaggerated for clarity.

It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, are sometimes used herein for ease of description to describe one element or feature's relationship to another element(s) or feature(s) as illustrated in the figures. It will be understood, however, that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (for example, rotated 90 degrees or at other orientations), and the spatially relative descriptors used herein should be interpreted accordingly.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to necessarily illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

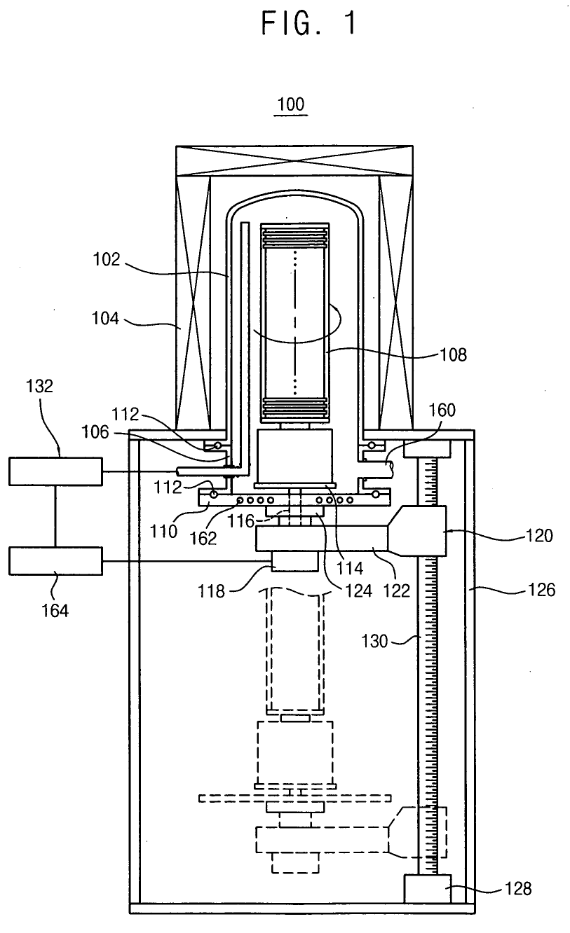

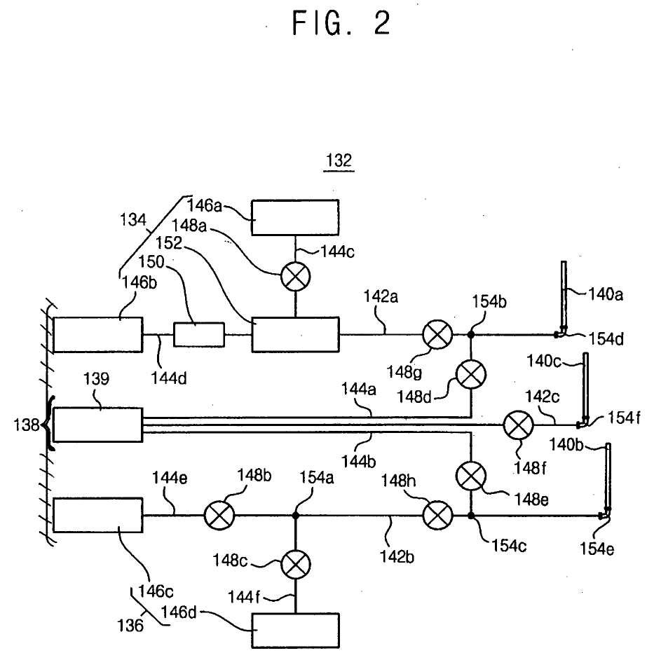

FIG. 1 is a schematic cross-sectional view illustrating an apparatus for forming a titanium nitride layer in accordance with an exemplary embodiment of the present invention. FIG. 2 is a block diagram illustrating a gas supply system for an apparatus for forming the titanium nitride layer as seen in FIG. 1.

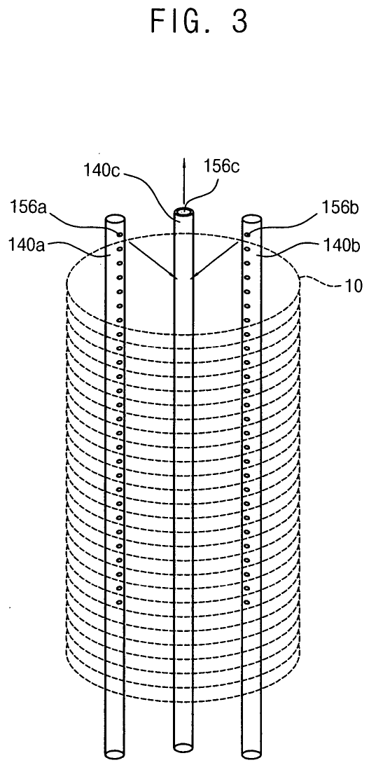

An apparatus 100 as shown in FIG. 1 may be advantageously employed for forming a titanium nitride layer on a semiconductor substrate 10 (refer to FIG. 3) such as a silicon wafer or a silicon on insulator (SOI) substrate.

Referring to FIG. 1, the apparatus 100 includes a process chamber 102 comprising a batch-type vertical reaction furnace. The process chamber 102 may have a vertical cylindrical shape of which a bottom face is open. The process chamber 102 may be formed of a refractory material such as quartz.

The apparatus 100 also includes a heating furnace 104 enclosing the process chamber 102 and a cylindrical manifold 106 which is adapted to adjoin and/or engage with a lower portion of the process chamber 102.

The apparatus 100 further comprises a boat or support 108 for supporting a plurality of semiconductor substrates 10, the substrates being separated by predetermined (preferably equal) intervals along a vertical axis. The boat 108 is inserted into the process chamber 102 through the open bottom face of the process chamber 102 which is located below the manifold 106. A lid member 110 disposed below the manifold 106 closes the open bottom face of the process chamber 102 after the semiconductor substrates 10 are loaded into the process chamber 102. Sealing members 112 are disposed between the lid member 110 and the manifold 106 and also between the process chamber 102 and the manifold 106 so as to seal up the process chamber 102 during the layer formation process.

The boat 108 is preferably disposed on a turntable 114 coupled to an upper portion of a rotation axel 116. The apparatus 100 preferably further includes a rotation driving unit 118 and a vertical driving unit 120. The rotation driving unit 118 is disposed beneath a horizontal arm 122 of the vertical driving unit 120. The lid member 110 is positioned over the horizontal arm 122 of the vertical driving unit 120.

A mechanical seal 124 is disposed between the lid member 110 and the horizontal arm 122 of the vertical driving unit 120 to prevent leakage of gases through a gap between the rotation axel 116 and the lid member 110. The rotation axel 116 connects the turntable 114 to the rotation driving unit 118 through the mechanical seal 124 and the horizontal arm 122.

The manifold 106 is disposed at an upper portion of a load-lock chamber 126 (or a transfer chamber). The manifold 106 is adapted to move between the process chamber 102 and the load-lock chamber 126 along the vertical direction.

The vertical driving unit 120 includes the horizontal arm 122, a vertical driving member 128 and a driving axel 130. The vertical driving member 128 provides the horizontal arm 122 with a vertical driving force to move the horizontal arm 122 along the vertical direction. The vertical driving force is transferred to the horizontal arm 122 through the driving axel 130.

The vertical driving member 128 may include a first motor, and the driving axel 130 may include a lead screw that is revolved by a rotation force provided from the first motor. The horizontal arm 122 is coupled to the driving axel 130 so that the horizontal arm 122 may be vertically moved by the driving axel 130.

The rotation driving unit 118 may further include a second motor. A driving gear is connected to such second motor and an idler gear is coupled to the rotation axel 116. A timing belt is disposed between the driving gear and the idler gear. The second motor thus provides a rotation force to the rotation axel 116 through the driving gear, the idler gear and the timing belt. In an exemplary embodiment of the present invention, the idler gear may be directly coupled to the driving gear without the timing belt.

Referring to FIG. 2, a gas supply system 132 of the apparatus 100 (see FIG. 1) alternately provides source gases or purge gases into the process chamber 102. The source gases are provided onto the semiconductor substrates 10 loaded in the process chamber 102 by the boat 108 so as to form desired layers on the semiconductor substrates 10, respectively. The purge gases are introduced into the process chamber 102 to purge the process chamber 102 between the various layer formation steps.

In particular, the gas supply system 132 includes a first gas supply unit 134 (comprising elements 146a, 146b, 148a, 150 and 152, as hereinafter described), a second gas supply unit 136 (comprising elements 146c and 146d, as hereinafter described), and a third gas supply unit 138. The first and the second gas supply units 134 and 136 provide a first source gas and a second source gas respectively and at the appropriate times onto the semiconductor substrates 10 to form titanium nitride layers on the semiconductor substrates 10. The first source gas may include a titanium precursor, and the second source gas may include a nitrogen gas. The third gas supply unit 138 provides the purge gases into the process chamber 102 to purge reaction gases and byproducts from the chamber between the various layer formation steps.

In an exemplary embodiment of the present invention, the titanium precursor may be selected from the group consisting of TiCl₄, tetra-tertiary-butoxy-titanium (Ti(OtBu)₄), tetrakis-dimethyl-amino-titanium (TDMAT; Ti(NMe₂)₄), tetrakis-diethyl-amino-titanium (TDEAT; Ti(NEt₂)₄), tetrakis-ethyl-methyl-amino-titanium (TEMAT; Ti(NEtMe)₄), etc. The second source gas may include an NH₃ gas. The first source gas and the second source gas may be carried into the process chamber 102 using a first carrier gas and a second carrier gas, respectively. The purge gases, the first carrier gas and the second carrier gas may, for example, consist essentially of argon (Ar) gases, nitrogen (N₂) gases, and mixtures thereof.

The gas supply system 132 is connected through gas supply lines to nozzle pipes 140a, 140b and 140c, which are disposed in the manifold 106 (see FIG. 1). Particularly, the first gas supply unit 134 of the gas supply system 132 is connected to a lower end portion of a first nozzle pipe 140a, which is disposed in the manifold 106, through a first gas supply line 142a. The second gas supply unit 136 is connected to a lower end portion of a second nozzle pipe 140b, which is disposed in the manifold 106, through a second gas supply line 142b. The third gas supply unit 138 is connected to the first gas supply line 142a and also to the second gas supply line 142b through a first connection line 144a and a second connection line 144b, respectively. Additionally, the third gas supply unit 138 is connected to a lower end portion of a third nozzle pipe 140c, which is also disposed in the manifold 106, through a third gas supply line 142c. Thus, the purge gases can be introduced into the process chamber 102 through any or all of the first connection line 144a, the first gas supply line 142a, the first nozzle pipe 140a, the second connection line 144b, the second gas supply line 142b, the second nozzle pipe 140b, the third gas supply line 142c and the third nozzle pipe 140c.

Referring further to FIGS. 1 and 2, the first gas supply unit 134 comprises the following elements: a first reservoir 146a, a first valve 148a, a second reservoir 146b, a liquid mass flow controller 150, and a vaporizer 152. The first carrier gas is provided from the first reservoir 146a. The first valve 148a adjusts a flow rate of the first carrier gas. The second reservoir 146a stores the titanium precursor in the liquid phase. The liquid mass flow controller 150 controls a flow rate of the titanium precursor in the liquid phase, and the vaporizer 152 evaporates the titanium precursor which was fed to vaporizer 152 in the liquid phase. Alternatively, the first gas supply unit 134 may include a bubbler (not shown) instead of the vaporizer 152 to evaporate the liquid-phase titanium precursor.

The first reservoir 146a and the vaporizer 152 are connected to each other through the third connection line 144c. The first valve 148a is installed in the third connection line 144c. The second reservoir 146b is connected to the vaporizer 152 through a fourth connection line 144d. The liquid mass flow controller 150 is installed in the fourth connection line 144d.

The liquid-phase titanium precursor is vaporized in the vaporizer 152, and then the vaporized titanium precursor (i.e., the titanium precursor which is now substantially in a gaseous or vaporized phase) is provided onto the semiconductor substrates 10 together with the first carrier gas (with which the gaseous-phase titanium precursor is mixed) through the first gas supply line 142a and first nozzles (not shown in FIG. 2) associated with the first nozzle pipe 140a.

The second gas supply unit 136 comprises the following elements: a third reservoir 146c and a fourth reservoir 146d. The third reservoir 146c provides the second carrier gas and the fourth reservoir 146d provides the NH₃ gas, the second carrier gas and the NH₃ gas being mixed at first connecting member 154a before being passed to the process chamber 102. The second gas supply unit 136 is connected to the second nozzle pipe 140b through the second gas supply line 142b.

The second gas supply line 142b is connected to the third reservoir 146c and the fourth reservoir 146d through a fifth connection line 144e and a sixth connection line 144f, respectively. The first connecting member 154a connects the second gas supply line 142b to the fifth connection line 144e and the sixth connection line 144f. A second valve 148b is installed in the fifth connection line 144e to adjust a flow rate of the second carrier gas. A third valve 148c is installed in the sixth connection line 144f to control a flow rate of the NH₃ gas.

The third gas supply unit 138 includes a fifth reservoir 139 for providing the purge gases which are periodically directed into the process chamber 102. The first connection line 144a is extended from the reservoir 139 of the third gas supply unit 138, and then is connected to the first gas supply line 142a through a second connecting member 154b. The second connection line 144b is extended from the reservoir 139 of the third gas supply unit 138, and then is connected to the second gas supply line 142b through a third connecting member 154c. A fourth valve 148d is installed in the first connection line 144a to regulate the flow rates of the purge gases provided through the first nozzle pipes 140a. A fifth valve 148e is installed in the second connection line 144b to control the flow rates of the purge gases supplied through the second nozzle pipe 140b.

The reservoir 139 of the third gas supply unit 138 is connected to the third nozzle pipe 140c through the third gas supply line 142c so as to rapidly purge the process chamber 102. A sixth valve 148f is installed in the third gas supply line 142c to control the flow rates of the purge gases provided through the third nozzle pipe 140c.

In the manifold 106, the first, the second and the third gas supply lines 142a, 142b and 142c are connected to the first, the second and the third nozzle pipes 140a, 140b and 140c, respectively, through a fourth connecting member 154d, a fifth connecting member 154e and a sixth connecting member 154f, respectively.

As shown in FIG. 2, a seventh valve 148g is installed in the first gas supply line 142a between the vaporizer 152 and the second connecting member 154b in order to control the flow rate of the combined stream of first source gas and first carrier gas. Additionally, an eighth valve 148h is installed in the second gas supply line 142b between the first connecting member 154a and the third connecting member 154c so as to regulate the flow rate of the combined stream of second source gas and second carrier gas. In an exemplary embodiment of the present invention, the first carrier gas, the second carrier gas and the purge gases may be the same and, thus, may be provided into the process chamber 102 from a single reservoir, although as shown in FIG. 2 these gases are independently provided from separate reservoirs.

The first gas supply line 142a may be maintained at a predetermined elevated temperature by any appropriate means to prevent the mixed gas stream including the titanium precursor in the gas phase from condensing. When the titanium precursor includes TiCl₄ gas, for example, a portion of the titanium precursor may condense at a temperature of about 70° C. or lower. This condensed portion of the titanium precursor may contaminate various elements of the apparatus 100 for forming the titanium nitride layer. Further, the condensed portion of the titanium precursor may react with the NH₃ gas at a temperature below about 130° C. to generate a powder of NH₄Cl. Thus, the first gas supply line 142a is preferably maintained at a temperature of about 150 to about 250° C. to prevent the titanium precursor including TiCl₄ gas from condensing therein.

In another exemplary embodiment of the present invention, a first heating jacket (not shown) may be installed around the first gas supply line 142a so that the mixed gas stream including the first source gas may maintain a previously set temperature of, for example, about 200° C.

When the second source gas has a temperature substantially lower than that of the first source gas, an undesired reaction of the titanium precursor may occur in the process chamber 102 because of a temperature difference between the first source gas and the second source gas. Hence, the second source gas may advantageously be maintained at a temperature substantially identical to that of the first source gas. In another exemplary embodiment of the present invention, a second heating jacket (not shown) may be installed around the second gas supply line 142b so that the second source gas may be maintained at a previously set temperature of, for example, about 200° C.

Additionally, the purge gases will also preferably be maintained at a temperature substantially identical to that of the first source gas and that of the second source gas. Accordingly, a third heating jacket (not shown), a fourth heating jacket (not shown) and a fifth heating jacket (not shown) may be installed around the first connection line 144a, the second connection line 144b and the third gas supply line 142c, respectively.

FIG. 3 is a perspective view schematically illustrating the first nozzle pipe 140a, the second nozzle pipe 140b and the third nozzle pipe 140c which are shown connecting to the gas supply system 132 in FIG. 2.

Referring to FIGS. 1 and 3, the first nozzle pipe 140a is adjacent to the plurality of semiconductor substrates 10 loaded in the boat 108. The first nozzle pipe 140a extends along the vertical direction from the first gas supply line 142a (FIG. 2). The first nozzle pipe 140a includes a plurality of first nozzles 156a for spraying the mixed gas stream containing the first source gas onto the semiconductor substrates 10. The first nozzles 156a are disposed at lateral portions of the first nozzle pipe 140a along the vertical direction and are preferably separated by or spaced at (preferably equal) predetermined intervals so that the mixed gas stream containing the first source gas sprayed from the first nozzles 156a flows along surfaces of the semiconductor substrates 10 loaded in the boat 108. Particularly, the first nozzles 156a provide the mixed gas stream containing the first source gas into spaces among and between the semiconductor substrates 10 after the mixed gas stream containing the first source gas is sprayed from the first nozzles 156a toward central portions of the semiconductor substrates 10.

The second nozzle pipe 140b is also disposed adjacent to the semiconductor substrates 10 loaded in the boat 108, and extends generally in parallel relative to the first nozzle pipe 140a. The second nozzle pipe 140b includes a plurality of second nozzles 156b for spraying the mixed gas stream containing the second source gas onto the semiconductor substrates 10. The second nozzles 156b are disposed at lateral portions of the second nozzle pipe 140b along the vertical direction and are preferably separated by or spaced at predetermined intervals so that the mixed gas stream containing the second source gas sprayed from the second nozzles 156b flows along the surfaces of the semiconductor substrates 10 loaded in the boat 108. In particular, the second nozzles 156b provide the mixed gas stream containing the second source gas into the spaces among and between the semiconductor substrates 10 after the mixed gas stream containing the second source gas is sprayed from the second nozzles 156b toward central portions of the semiconductor substrates 10.

The third nozzle pipe 140c is disposed generally between the first nozzle pipe 140a and the second nozzle pipe 140b. The third nozzle pipe 140c extends generally in parallel relative to the first and the second nozzle pipes 140a and 140b. The third nozzle pipe 140c has a third nozzle 156c for rapidly purging the process chamber 102. The third nozzle 156c is disposed at an upper end portion of the third nozzle pipe 140c. The purge gases are vertically sprayed from the third nozzle 156c.

In a preferred embodiment, the purge gases are substantially simultaneously introduced into the process chamber 102 through the first nozzles 156a, the second nozzles 156b and the third nozzle 156c. A first portion of the purge gases, namely that supplied through the first nozzles 156a, may have a controlled flow rate substantially identical to that of the first carrier gas. In addition, a second portion of the purge gases, namely that provided through the second nozzles 156b, may have an adjusted flow rate substantially identical to that of the second carrier gas. A third portion of the purge gases, namely that supplied through the third nozzle 156c, may have a flow rate of about two to about eight times larger than that of the first carrier gas and/or that of the second carrier gas so as to rapidly purge the upper regions of process chamber 102. The first carrier gas may have a controlled flow rate substantially identical to that of the second carrier gas. As a result, a combined flow rate of the purge gases to process chamber 102 as provided through the first nozzles 156a, the second nozzles 156b, and the third nozzle 156c may range from about four times to about ten times larger than the flow rate of the first carrier gas or that of the second carrier gas.

An angle between a spray direction of the mixed gas stream containing the first source gas and a spray direction of the mixed gas stream containing the second source gas may be in a range of about 20 to about 80°. The first nozzle pipe 140a, the second nozzle pipe 140b and the third nozzle pipe 140c may be separated from central vertical axis of the process chamber 102 and of the array of semiconductor substrates 10 by substantially identical distances, respectively. The first nozzle pipe 140a, the second nozzle pipe 140b and the third nozzle pipe 140c may, for example, have inner diameters of about 2.5 to about 15 mm. Each of the first nozzles 156a and the second nozzles 156b may, for example, have an inner diameter of about 0.5 to about 2.0 mm. In an exemplary embodiment of the present invention, the first and the second nozzle pipes 140a and 140b have inner diameters of about 5 mm, respectively. Also in this embodiment, each of the first and the second nozzles 156a and 156b has an inner diameter of about 1.5 mm. The third nozzle pipe 140c may, for example, have an inner diameter substantially identical to that of the first nozzle pipe 140a and that of the second nozzle pipe 140b. For example, in the exemplary embodiment, the third nozzle pipe 140c has an inner diameter of about 5 mm.

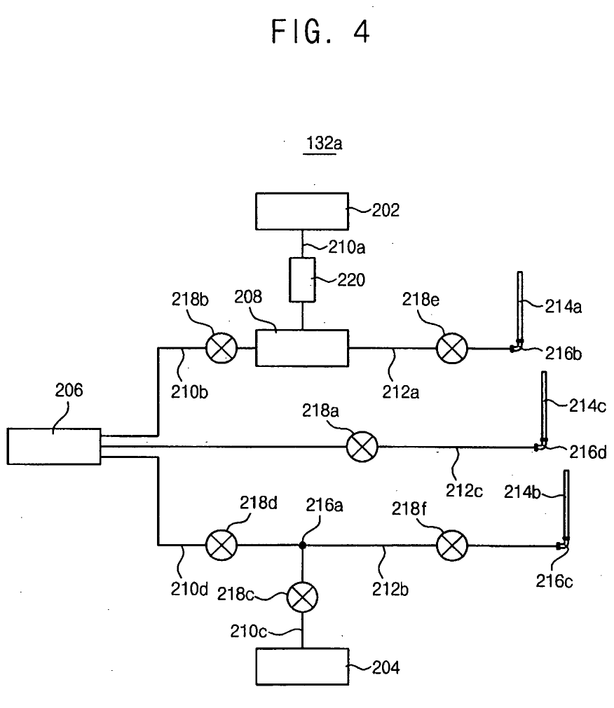

FIG. 4 is a block diagram illustrating a gas supply system in accordance with another example embodiment of the present invention.

Referring to FIG. 4, a gas supply system 132a as shown in FIG. 4 includes a first reservoir 202, a second reservoir 204, a third reservoir 206 and a vaporizer 208. The first reservoir 202 stores a titanium precursor in a liquid phase and the second reservoir 204 provides an NH₃ gas for introduction into the process chamber 102. The third reservoir 206 provides an argon gas or a nitrogen gas for introduction into the process chamber, and the vaporizer 208 evaporates the titanium precursor from the liquid phase into a gaseous or vaporized phase. The argon gas or the nitrogen gas supplied from the third reservoir 206 may be used as a first carrier gas and/or a second carrier gas for mixing with and carrying the titanium precursor and the NH₃ gas to the process chamber. Additionally, the argon gas or the nitrogen gas provided from the third reservoir 206 may also be used as a purge gas for purging the process chamber 102.

The first reservoir 202 as shown in FIG. 4 is connected to the vaporizer 208 through a first connection line 210a, and the third reservoir 206 is connected to the vaporizer 208 through a second connection line 210b. The vaporizer 208 is coupled to a first nozzle pipe 214a through a first gas supply line 212a. After the titanium precursor in the liquid phase is provided from first reservoir 202 through the first connection line 210a, the titanium precursor is mixed with the carrier gas and vaporized in the vaporizer 208. Then, the mixed gas stream containing the vaporized titanium precursor together with the argon gas or the nitrogen gas supplied from the third reservoir 206 is provided to the semiconductor substrates 10 in process chamber 102 through the first gas supply line 212a and the first nozzle pipe 214a.

The second reservoir 204 is connected to a second nozzle pipe 214b through a third connection line 210c and a second gas supply line 212b. The third reservoir 206 is connected to the second nozzle pipe 214b through a fourth connection line 210d and the second gas supply line 212b. That is, the third and the fourth connection lines 210c and 210d connect the second reservoir 204 and the third reservoir 206 respectively to the second gas supply line 212b.

The third connection line 210c, the fourth connection line 210d and the second gas supply line 212b are connected to one another through a first connecting member 216a. The first gas supply line 212a and the second gas supply line 212b are connected to the first nozzle pipe 214a and the second nozzle pipe 214b respectively through a second connecting member 216b and a third connecting member 216c, respectively.

The third reservoir 206 is connected to a third nozzle pipe 214c through a third gas supply line 212c and is utilized to rapidly purge the process chamber 102 between layer formation steps. A first valve 218a is installed in the third gas supply line 212c to control a flow rate of the purge gases. The third gas supply line 212c is connected to the third nozzle pipe 214c through a fourth connecting member 216d.

A liquid mass flow controller 220 is installed in the first connection line 210a to adjust a flow rate of the liquid-phase titanium precursor. A second valve 218b is installed in the second connection line 210b to control a flow rate of the argon gas or a flow rate of the nitrogen gas which is employed as either the first carrier gas or the purge gases or both. A third valve 218c is mounted in the third connection line 210c to control a flow rate of the NH₃ gas from reservoir 204. A fourth valve 218d is installed in the fourth connection line 210d to control a flow rate of the argon gas or a flow rate of the nitrogen gas which is employed as either the second carrier gas or the purge gases or both.

In an exemplary embodiment of the present invention, a fifth valve 218e and a sixth valve 218f may be located in the first gas supply line 212a and in the second gas supply line 212b, respectively. The fifth valve 218e controls a flow rate of the mixed gas stream containing the first source gas, and the sixth valve 218f regulates a flow rate of the mixed gas stream containing the second source gas.

Referring again to FIG. 1, a vacuum pump (not shown) is connected to the manifold 106 through a vacuum line 160 and an isolation valve (not shown) so as to vacuumize the process chamber 102. A heating furnace 104 is disposed adjacent to a sidewall and a ceiling or upper region of the process chamber 102. The process chamber may, for example, be operated at a pressure of about 0.3 to about 1.0 Torr and a temperature of about 350 to about 550° C. during formations of the titanium nitride layers on the semiconductor substrates 10. For a specific example, the process chamber 102 has a temperature of about 450° C.

An inside region of the manifold 106 may have a temperature substantially lower than that of an inside region of the process chamber 102. A heater 162 may be provided in the lid member 110 to compensate for such a temperature difference between the inside region of the manifold 106 and the inside region of the process chamber 102. The heater 162 heats the inside region of the manifold 106 so that the inside of the manifold 106 has a temperature substantially identical to that of the inside of the process chamber 102. The heater 162 may include an electrical resistance coil. In an exemplary embodiment of the present invention, the heater 162 may be disposed inside a sidewall of the manifold 106. Alternatively, the heater 162 may be located on an inner sidewall of the manifold 106.

A control unit 164 controls the gas supply system 132, the vertical driving unit 120 and the rotation driving unit 118. After loading the boat 108 including the semiconductor substrates 10 into the process chamber 102, the flow rates and flow times of the gases provided from the gas supply system 132 are all preferably controlled by the control unit 164. The control unit 164 can further control the rotation speed of the semiconductor substrates 10 so as to uniformly form the titanium nitride layers on the semiconductor substrates 10.

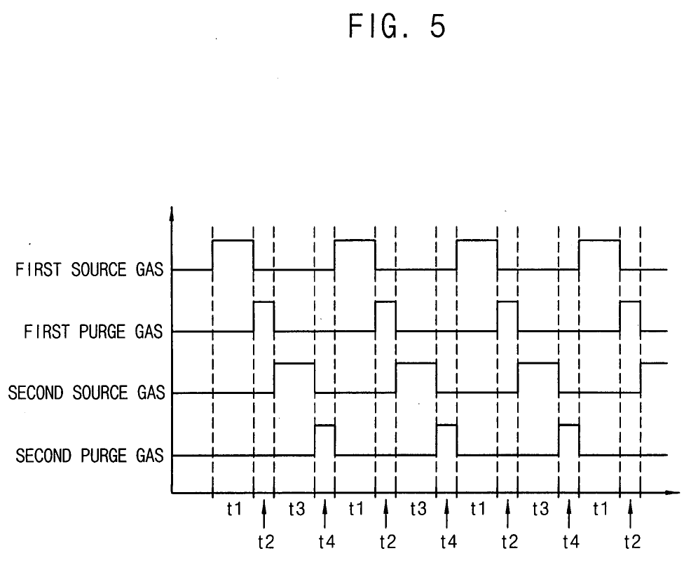

FIG. 5 is a timing diagram illustrating a representative sequence of supply times of source gases and purge gases using the gas supply system 132 as shown in FIG. 2.

Referring to FIGS. 1, 2, 3 and 5, the first source gas is provided onto the semiconductor substrates 10 for about a first time period t1 through the first nozzles 156a, thereby forming titanium layers on the semiconductor substrates 10. Each of the titanium layers includes chemisorbed titanium precursor.

A first purge gas is introduced into the process chamber 102 for about a second time period t2 through the first nozzles 156a and the second nozzles 156b, and also the third nozzle 156c so as to rapidly purge the process chamber 102. The first purge gas provided through the first and the second nozzles 156a and 156b is introduced onto the semiconductor substrates 10, whereas the first purge gas supplied through the third nozzle 156c is introduced toward the ceiling or upper region of the process chamber 102 for complete and rapid purging. The first purge gas provided through the third nozzle 156c flows along the ceiling and the sidewall of the process chamber 102, and then is exhausted from the process chamber 102 through the vacuum line 160. Portions of the titanium precursor physically adsorbed to the semiconductor substrates 10 are also removed from the process chamber 102 by the purge gases provided through the first and the second nozzles 156a and 156b.

A second source gas is then provided onto the titanium layers on the semiconductor substrates 10 for about a third time period t3 through the second nozzles 156b to thereby form titanium nitride layers on the semiconductor substrates 10. When the first source gas includes TiCl₄ gas, the second gas ordinarily includes NH₃ gas. When the second source gas is provided onto the previously formed titanium layers, the titanium layers are converted into titanium nitride layers by reaction between the second source gas and the titanium layers. Chlorine ions contained in the titanium layers are removed from the titanium nitride layers in accordance with the reaction between the second source gas and the titanium layers.

A second purge gas is then introduced into the process chamber 102 for about a fourth time period t4 through the first nozzles 156a, the second nozzles 156b, and the third nozzle 156c in order to rapidly purge the process chamber 102. Reaction by-products and remaining second source gas are thus removed from the reaction chamber 102 together with the second purge gas.

As described above, the second time period t2 and the fourth time period t4 may be relatively brief because the first and the second purge gases, respectively, are additionally provided through the third nozzle 156c as well as through the first and second nozzles. For example, a ratio among the first time period t1, the second time period t2, the third time period t3 and the fourth time period t4 is typically in a range of about 1.0:0.4 to 0.8:1.0:0.4 to 0.8. To reduce the second time period t2 for providing the first purge gas and the fourth time period t4 for providing the second purge gas, a flow rate of the first purge gas and a flow rate of the second purge gas may be about four times to about ten times larger than the flow rate of the first carrier gas or the flow rate of the second carrier gas, respectively. To adjust the flow rates and supply times of the source, the carrier and the purge gases, the control unit 164 appropriately controls operations of the liquid mass flow controller 150 and the valves 148a, 148b, 148c, 148d, 148e and 148f.

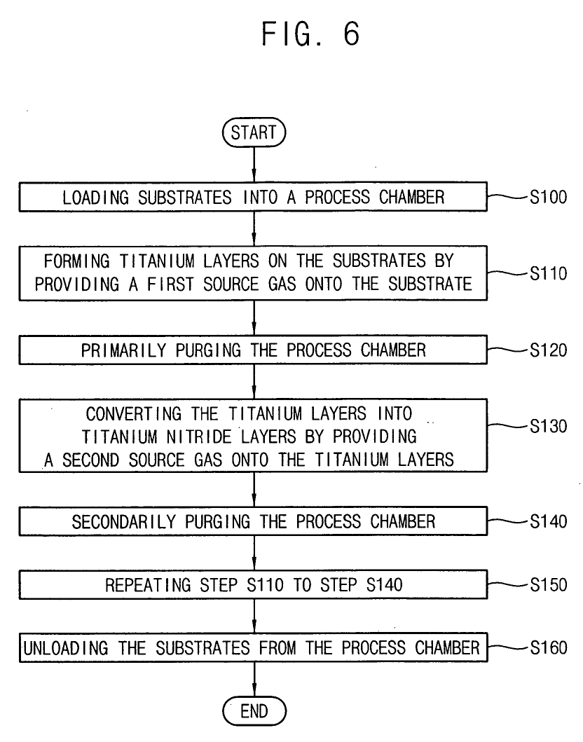

FIG. 6 is a flow chart illustrating a method of forming a titanium nitride layer in accordance with an example embodiment of the present invention.

Referring to FIGS. 2, 3 and 6, the semiconductor substrates 10 are loaded into the process chamber 102 in step S100. The semiconductor substrates 10 are vertically loaded into the boat 108, and are separated by predetermined intervals or spacing. The surfaces of the semiconductor substrates 10 are substantially horizontally disposed in the boat 108. The boat 108 including the semiconductor substrates 10 is loaded into the process chamber 102 through the manifold 106 by means of the vertical driving unit 120.

In an exemplary embodiment of the present invention, the semiconductor substrates 10 comprise semiconductor structures for use in fabricating semiconductor devices. For example, each of the semiconductor structures may include a transistor and a capacitor, having a dielectric layer and a lower electrode. The transistor may also include a gate structure and impurity regions serving as source/drain regions. The lower electrode of the capacitor may be electrically connected to one of the impurity regions. The dielectric layer of the capacitor may be formed on the lower electrode. The lower electrode may be formed using polysilicon doped with impurities, and the dielectric layer may be formed using hafnium oxide (HfO₂). These and similar semiconductor structures are familiar to those skilled in the art.

In step S110, the first source gas is provided through the first nozzles 156a onto the semiconductor substrates 10 to thereby form titanium layers on the semiconductor substrates 10. When the titanium precursor includes TiCl₄ gas, the liquid mass flow controller 150 controls the flow rate of the titanium precursor to be, for example, about 200 mgm, and the first valve 148a adjusts the flow rate of the first carrier gas to be, for example, about 0.5 slm. The first source gas may be provided into the process chamber 102 for a period of about 10 seconds.

In step S120, the first purge gas is provided into the process chamber 102 through the first nozzles 156a, the second nozzles 156b and the third nozzle 156c to thereby remove remaining first source gas and some portion of the physically absorbed titanium precursor from the process chamber 102. The first purge gas may include nitrogen gas, for example. The nitrogen gas may be provided into the process chamber 102 through the first nozzles 156a at a flow rate of about 0.5 slm, for example, and may also be provided through the second nozzles 156b at a flow rate of about 0.5 slm. The nitrogen gas may be additionally provided into the process chamber 102 through the third nozzle 156c at a flow rate, for example, of about 2 slm. Accordingly, the process chamber 102 is rapidly purged by the nitrogen gas. For example, the first purge gas may only need to be provided into the process chamber 102 for about 5 seconds to effect on a substantially complete purge of the chamber.

In step S130, the titanium layers formed on the semiconductor substrates 10 are converted into titanium nitride layers by providing the second source gas into the process chamber 102 through the second nozzles 156b. The second carrier gas mixed with the NH₃ gas may be provided into the process chamber 102 through the second valve 148b at a flow rate of about 0.5 slm, for example, and may also be provided through the third valve 148c at a flow rate of about 0.5 slm. For example, the second source gas is provided into the process chamber 102 for about 10 seconds.

After forming the titanium nitride layers on the semiconductor substrates 10, the second purge gas is introduced into the process chamber 102 in step S140. The second purge gas is provided into the process chamber 102 through the first nozzles 156a, the second nozzles 156b and the third nozzle 156c so as to remove the reaction by-products and the remaining second source gas from the process chamber 102. The second purge gas, which may include nitrogen gas, for example, may be provided into the process chamber 102 through the first nozzles 156a at a flow rate of about 0.5 slm, and may also be introduced through the second nozzles 156b at a flow rate of about 0.5 slm. The second purge gas may be additionally introduced into the process chamber 102 through the third nozzle 156c at a flow rate of about 2 slm. Thus, the process chamber 102 is rapidly purged by the second purge gas. For example, the second purge gas may only need to be introduced into the process chamber 102 for about 5 seconds to effect on a substantially complete purge.

In the above-described atomic layer deposition (ALD) process for forming the titanium nitride layers, each of the titanium nitride layers may typically have a thickness of about 0.2 to about 0.3 Å after performing one unit cycle, defined as consisting of one set of the sequence of steps from step S100 to step S140. This titanium nitride layer may have good step coverage. Since the semiconductor substrates 10 are preferably constantly revolved by the rotation driving unit 118 during the unit cycle, each of the titanium nitride layers may have a uniform thickness. When the titanium precursor includes TiCl₄ gas and the titanium nitride layer is formed on a dielectric layer, undesired particles generated by a reaction between chlorine ions and the dielectric layer may be largely if not completely prevented. For example, hafnium (IV) chloride (HfCl₄) generated by a reaction between hafnium oxide in the dielectric layer and the chlorine ions may be prevented so that the dielectric layer may have improved dielectric characteristics.

In the unit cycle comprising the set of steps consisting of step S100 to step S140, the control unit 164 preferably controls the liquid mass flow controller 150 and the valves 148a, 148b, 148c, 148d, 148e and 148f. The process chamber 102 has a pressure, for example, of about 0.3 to about 1 Torr and a temperature, for example, of about 450° C.

Referring now to FIGS. 1, 2 and 6, the unit cycle, comprising the sequence of steps consisting of step S100 to step S140, is repeatedly performed to obtain titanium nitride layers having a desired thickness on the semiconductor substrates 10. In step S150, the thickness of the formed titanium nitride layers can be measured to determine whether the unit cycle needs to be repeated. Alternatively, the unit cycle can be repeated a predetermined number of times to obtain a desired layer thickness.

In step S160, the semiconductor substrates 10 having the titanium nitride layers of the desired thickness are unloaded from the process chamber 102. That is, the boat 108 having the semiconductor substrates 10 is carried out of the process chamber 102 into the load-lock chamber 126 (see FIG. 1) by the vertical driving unit 120.

According to the present invention, a titanium nitride layer having a desired thickness and good step coverage may be easily formed by an ALD process using an apparatus according to this invention for forming the titanium nitride layer. In addition, the titanium nitride layer may have substantially uniform thickness because the titanium nitride layer is preferably formed on a semiconductor substrate which is rotated at a constant speed during layer formation.

When the titanium nitride layer is formed using a TiCl₄ gas and an NH₃ gas, chlorine ions may be removed by a reaction between the chlorine ions and the NH₃ gas so that the titanium nitride layer may have a low specific resistance, and an underlying dielectric layer including hafnium oxide may have enhanced dielectric characteristics. Further, since a process chamber used for forming the titanium nitride layer according to this invention is rapidly purged between layer formation steps in a formation of the titanium nitride layer, a time for forming the titanium nitride layer may be greatly reduced relative to conventional techniques.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of this invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with all reasonable equivalents of the claims as understood by those skilled in this art to be included therein.

What is claimed is:

1. A method of forming titanium nitride layers on one or more substrates comprising:
forming titanium layers on substrates loaded in a process chamber by bringing a first source gas, which includes a titanium precursor, into contact with the substrates for a first time period;
rapidly purging the process chamber by introducing a first purge gas into the process chamber for a second time period which is shorter than the first time period;
converting the titanium layers into titanium nitride layers by bringing a second source gas, which includes nitrogen, into contact with the titanium layers for a third time period which is substantially identical to the first time period; and
rapidly purging the process chamber by introducing a second purge gas into the process chamber for a fourth time period which is substantially identical to the second time period.

2. The method of claim 1, wherein the substrates are vertically stacked at predetermined intervals and the substrates are loaded substantially in parallel into the process chamber.

3. The method of claim 2, wherein the first source gas and the second source gas are provided into the process chamber through a plurality of first nozzles and a plurality of second nozzles, respectively, the first and the second nozzles being disposed generally in a parallel array adjacent to the substrates.

4. The method of claim 3, wherein the first purge gas and the second purge gas are introduced into the process chamber at appropriate times through the first nozzles, the second nozzles, and also through a third nozzle disposed between the first nozzles and the second nozzles.

5. The method of claim 4, wherein at least portions of the first and the second purge gases introduced through the first and the second nozzles flow along surfaces of the substrates, and at least portions of the first and the second purge gases introduced through the third nozzle are sprayed into an interior upper region of the process chamber.

6. The method of claim 1, wherein the process chamber is maintained at a temperature of about 350 to about 550° C.

7. The method of claim 1, wherein the titanium precursor is selected from the group consisting of TiCl₄, Ti(OtBu)₄, Ti(NMe₂)₄, Ti(NEt₂)₄ and Ti(NEtMe)₄.

8. The method of claim 1, wherein the second source gas consists essentially of NH₃.

9. The method of claim 1, wherein a ratio among the first time period, the second time period, the third time period and the fourth time period is in a range of about 1.0:0.4 to 0.8:1.0:0.4 to 0.8.

10. The method of claim 1, wherein a ratio among the first time period, the second time period, the third time period and the fourth time period is in a range of about 1.0:0.5:1.0:0.5.

11. The method of claim 1, wherein the first source gas is mixed with and carried to the process chamber using a first carrier gas, and the second source gas is mixed with and carried to the process chamber using a second carrier gas.

12. The method of claim 11, wherein a flow rate of the first purge gas is about four times to about ten times larger than a flow rate of the first carrier gas.

13. The method of claim 12, wherein the flow rate of the first purge gas is substantially identical to a flow rate of the second purge gas, and the flow rate of the first carrier gas is substantially identical to a flow rate of the second carrier gas.

14. The method of claim 13, wherein a flow rate of the first purge gas introduced through the first nozzles, a flow rate of the first purge gas introduced through the second nozzles, a flow rate of the second purge gas introduced through the first nozzles and a flow rate of the second purge gas introduced through the second nozzles are substantially identical to the flow rate of the first carrier gas or to the flow rate of the second carrier gas or both.

15. An apparatus for forming titanium nitride layers on one or more substrates, the apparatus comprising:
a process chamber;
a boat disposed in the process chamber, the boat supporting a plurality of substrates;
a gas supply system for sequentially providing a first source gas, a first purge gas, a second source gas and a second purge gas into the process chamber, wherein the first source gas includes a titanium precursor for forming titanium layers on the substrates, the first purge gas substantially purges the process chamber after forming the titanium layer, the second source gas includes nitrogen for converting the titanium layers into titanium nitride layers, and the second purge gas substantially purges the process chamber after forming the titanium nitride layer; and
a control unit for controlling the gas supply system to sequentially provide the first source gas for a first time period, the first purge gas for a second time period shorter than the first time period, the second source gas for a third time period substantially identical to the first time period, and the second purge gas for a fourth time period substantially identical to the second time period.

16. The apparatus of claim 15, wherein the process chamber has a vertical cylindrical shape including an open bottom face.

17. The apparatus of claim 16, further comprising:
a heating furnace disposed substantially to enclose the process chamber, for heating the process chamber to a process temperature;
a manifold in engagement with a lower portion of the process chamber, the manifold having a cylindrical shape including an open upper face and an open bottom face; and
a vertical driving unit for loading/unloading the boat into/out of the process chamber through the manifold.

18. The apparatus of claim 17, wherein the vertical driving unit comprises:
a motor for generating a first rotation force;
a lead screw revolved by the first rotation force; and
a horizontal arm coupled to the lead screw, the horizontal arm being vertically moved by the lead screw.

19. The apparatus of claim 18, further comprising:
a lid member disposed on the horizontal arm to open and close the open bottom face of the manifold; and
a turntable disposed on the lid member to support the boat.

20. The apparatus of claim 19, wherein the vertical driving unit further comprises:
a second motor mounted on the horizontal arm to generate a second rotation force for revolving the boat; and
a rotation axel coupled to the turntable through the horizontal arm and the lid member for transferring the second rotation force to the boat.

21. The apparatus of claim 17, further comprising a heater for heating an inside region of the manifold.

22. The apparatus of claim 15, wherein the substrates are vertically loaded in the boat, and are separated by predetermined intervals.

23. The apparatus of claim 22, wherein the gas supply system comprises:
a first gas supply unit for providing the first source gas;
a second gas supply unit for providing the second source gas;
a third gas supply unit for providing the first purge gas and the second purge gas;
a first gas supply line for transferring the first source gas into the process chamber;
a second gas supply line for transferring the second source gas into the process chamber;
a third gas supply line for transferring the first purge gas and the second purge gas into the process chamber; and
connection lines for connecting the third gas supply unit to the first gas supply line and the second gas supply line.

24. The apparatus of claim 23, wherein the gas supply system further comprises:
a first nozzle pipe connected to the first gas supply line and vertically extending adjacent to the substrates in the process chamber, the first nozzle pipe including a plurality of first nozzles for sequentially providing the first source gas, the first purge gas and the second purge gas onto the substrates;
a second nozzle pipe connected to the second gas supply line and extending in parallel relative to the first nozzle pipe in the process chamber, the second nozzle pipe including a plurality of second nozzles for sequentially providing the second source gas, the first purge gas and the second purge gas onto the substrate; and
a third nozzle pipe disposed between the first nozzle pipe and the second nozzle pipe, and extended in parallel relative to the first and second nozzle pipes, the third nozzle pipe including a third nozzle for providing the first purge gas and the second purge gas into the process chamber.

25. The apparatus of claim 24, wherein the third nozzle is formed through an upper end portion of the third nozzle pipe, and the third nozzle substantially vertically sprays the first purge gas and the second purge gas toward an upper interior region of the process chamber.

26. The apparatus of claim 24, wherein the third nozzle has an inner diameter larger than the respective inner diameters of the first and the second nozzles.

27. The apparatus of claim 23, wherein the first gas supply unit comprises:
a first reservoir for providing a carrier gas;
a second reservoir for storing the titanium precursor in a liquid phase;
a vaporizer connected to the first and the second reservoirs to evaporate the titanium precursor from the liquid phase into a vaporized phase;
a valve installed in a first connection line that connects the first reservoir to the vaporizer, the valve controlling a flow rate of the carrier gas; and
a liquid mass flow controller installed in a second connection line that connects the second reservoir to the vaporizer, the liquid mass flow controller controlling a flow rate of the liquid-phase titanium precursor.
